(19) United States
(12) Patent Application Publication
(10) Pub. No.: US 2005/0264194 A1
(43) Pub. Date: Dec. 1, 2005

(54) Mold compound with fluorescent material and a light-emitting device made therefrom

(76) Inventors: Kee Yean Ng, Penang (MY); Janet Bee Yin Chua, Penang (MY)

Correspondence Address: AGILENT TECHNOLOGIES, INC.;Legal Department, DL 429, Intellectual Property Administration, P.O. Box 7599, Loveland, CO, 80537-0599, US

(21) Appl. No.: 10/852,786

(22) Filed: May 25, 2004

(51) Int. Cl. H01L 33/00

(52) U.S. Cl. 313/512

(57) ABSTRACT

A phosphor composition and light emitting device utilizing that composition is disclosed. The composition includes a suspension of phosphor particles that are uniformly distributed in a transparent medium that includes an epoxy, and a diffusive agent that includes diffusive particles of a transparent material. In one embodiment, the diffusive particles have a median particle size between 1 μm-5 μm. The diffusive agent can be made from both inorganic and organic material such as Barium Titanate, titanium Oxide, aluminum oxide, silicone oxide, calcium carbonate, melanin resin, CTU guanamine resin or benzoguanamine resin. Embodiments that further include adhesion promoters, hydrophobic agents, thixotropic agents and UV inhibitors are also disclosed. In one embodiment, the composition is in the form of a pellet suitable for transfer molding.

### BACKGROUND OF THE INVENTION

For the purposes of the present discussion, the present invention will be discussed in terms of a “white” emitting light-emitting diode ( LED); however, the methods taught in the present invention can be applied to wide range of LEDs. A white emitting LED that emits light that is perceived by a human observer to be “white” can be constructed by making an LED that emits a combination of blue and yellow light in the proper ratio of intensities. High intensity blue-emitting LEDs are known to the art. Yellow light can be generated from the blue light by converting some of the blue photons via an appropriate phosphor. In one design, a transparent layer containing dispersed particles of the phosphor covers an LED chip. The phosphor particles are dispersed in a potting material that surrounds the light-emitting surfaces of the blue LED. To obtain a white emitting LED, the thickness and uniformity of the dispersed phosphor particles must be tightly controlled.

In one class of prior art LEDs, the phosphor layer is fabricated by a molding process that utilizes a liquid mold compound that has the phosphor particles dispersed therein. The liquid mold compound is applied to a die having an LED thereon. The mold compound is then cured in place to provide the layer of phosphor particles. In one design, the LED is mounted on a heat sink in a well in a printed circuit board base. The well has reflective sides that form a reflective “cup” having the LED chip at the bottom thereof. The phosphor is mixed with a liquid casting epoxy and injected into the cup. The mixture is then heat-cured for 2 hours.

Unfortunately, this manufacturing system has a poor yield due to uneven phosphor dispersion in the reflecting cup. The density of the phosphor particles is larger than that of the liquid casting epoxy, and hence, the particles tend to settle toward the bottom of the reflector cup. As a result, the amount of phosphor over the chip is reduced, which, in turn, lowers the ratio of yellow to blue light generated by the completed device. Such a device emits light that is bluish-white rather than white.

In addition, the liquid casting epoxy tends to shrink during the heat curing process. This can leave a part in which the top of the chip is exposed. This also leads to a color shift that is undesirable.

One solution to the problems discussed above is to utilize a transfer molding process to form the phosphor coat over the die. In such a process, the phosphor particles are suspended in a partially cured epoxy resin. A pellet of the partially cured epoxy is subjected to sufficient heat and pressure to cause the epoxy to flow into a mold that covers the die. The resulting phosphor cap is formed in a time that is sufficiently small that the phosphor settling problems discussed above are substantially reduced.

Unfortunately, the phosphor-resin combination used in these devices has a number of problems. First, the adhesion of the phosphor layer to the semiconductor die can be insufficient to provide a reliable device. Second, a number of the phosphors are sensitive to moisture, and the resins utilized are sufficiently water permeable that this sensitivity reduces the lifetime of the device. Third, many of the light emitters utilized in these devices emit light in the blue or ultraviolet spectrum. This short wavelength light damages the epoxy resin, and hence, also shortens the life of the device.

### SUMMARY OF THE INVENTION

The present invention includes a phosphor composition and light emitting device utilizing that composition. The composition includes a suspension of phosphor particles that are uniformly distributed in a transparent medium that includes an epoxy, and a diffusive agent that includes diffusive particles of a transparent material. The diffusive particles have a median particle size between 1 μm-5 μm. The diffusive agent can be made from both inorganic and organic material such as Barium Titanate, titanium Oxide, aluminum oxide, silicone oxide, calcium carbonate, melanin resin, CTU guanamine resin or benzoguanamine resin. The diffuse agent is present in a concentration of less than or equal to 5 percent by weight. In one embodiment, the composition includes an adhesion promoter that improves the adhesion of the transparent medium to a semiconductor die. In one embodiment, the adhesion promoter includes a functional alkoxysiloxane. In one embodiment, the phosphor particles are coated with a hydrophobic agent such as silicone wax that protects the phosphor particles from moisture. In one embodiment, the composition includes a UV inhibitor such as resorcinol monobenzoate. In one embodiment, the composition includes a thixotropic agent that thickens the epoxy resin. In one embodiment, the composition is in the form of a pellet suitable for transfer molding. A light emitting device according to one embodiment of the present invention includes a semiconductor die having a light emitting device thereon that emits light at a first wavelength and a layer of the composition discussed above wherein the phosphor particles convert light of the first wavelength to light of a second wavelength.

### BRIEF DESCRIPTION OF THE DRAWINGS

FIG. 1 is a cross-sectional view of a prior art LED device 100 that is constructed on a substrate 110 with at least two terminals for supplying power to the device.

FIGS. 2 and 3 illustrate the manner in which the present invention applies a transfer molding process to fabricate an LED device 10.

### DETAILED DESCRIPTION OF THE PREFERRED EMBODIMENTS OF THE INVENTION

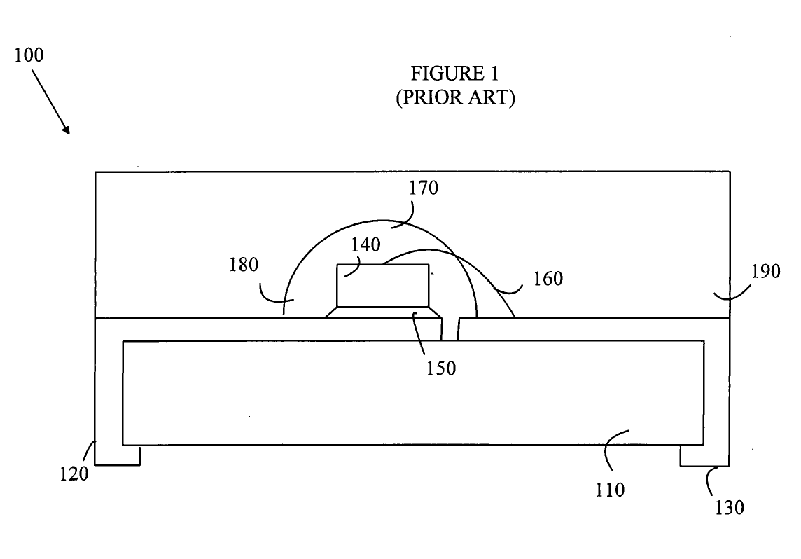

The manner in which the present invention provides its advantages can be more easily understood with reference to FIG. 1, which is a cross-sectional view of a prior art LED device 1 00. LED device 100 is constructed on a substrate 110 with at least two terminals for supplying power to the device. Exemplary terminals are shown at 120 and 130. In the embodiment shown in FIG. 1, an LED 140 is mounted on the first terminal 120 using an adhesive layer 150. LED 140 has one power terminal on the bottom surface of the LED and the other on a bond pad on the top surface. Adhesive layer 150 is constructed from an electrically conducting adhesive, and hence, provides an electrical connection to the power terminal on the bottom of the LED. A wire 160 that is typically connected using a conventional wire bonding process provides the power connection between the second terminal 130 and LED 140. A first encapsulant 170 containing phosphor particle 180 is dispensed around the LED. A second encapsulant 190 then seals the first encapsulant.

As noted above, in one class of prior art devices, the phosphor-containing encapsulant is typically produced by mixing the phosphor particles with the first encapsulant, which is typically an epoxy-based material. A sufficient quantity of the mixture must be made to process a large number of LEDs to provide sufficient economies of scale. This mixture is then placed in a reservoir and dispensed over the LEDs using a dispensing tool such as a syringe. The volume of the phosphor slurry varies because it is inherently difficult to dispense an accurate volume each time.

In addition, the time period over which the material is dispensed on the various individual LEDs is long enough to allow the phosphor particles to settle in the encapsulant reservoir. The phosphor particles have a specific density that is much greater than that of the epoxy material. Hence, the particles tend to settle and thus the dispensed slurry has a different proportion of phosphor as the dispensing process progresses. As a result, LED devices with different amounts of phosphor are produced as the process proceeds. This variation in phosphor results in LED devices having different colors. Hence, either short production times must be used or smaller production yields must be accepted.

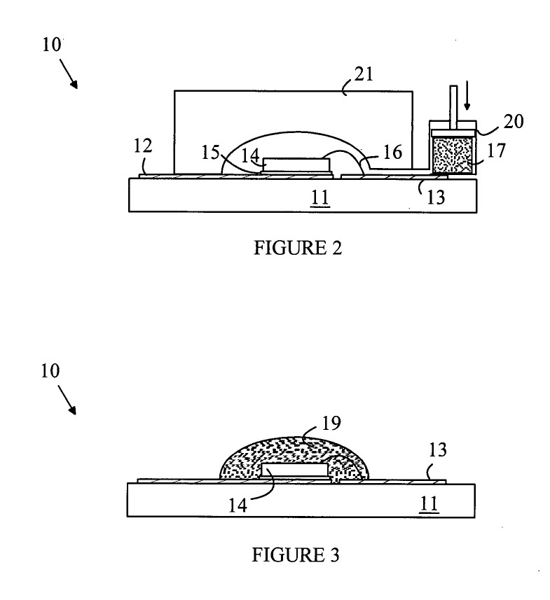

These settling and dispensing problems are reduced by utilizing a transfer molding process. Since transfer molding processes are known to the art, these processes will not be discussed in detail here. For the purposes of the present discussion, it is sufficient to note that these processes are based on reshaping a resin pellet. Refer now to FIGS. 2 and 3, which illustrate the manner in which the present invention applies a transfer molding process to fabricate an LED device 10. FIG. 2 is a cross-sectional view of an LED chip 14 mounted on a substrate 11 in a manner analogous to that discussed above with reference to FIG. 1. LED chip 14 has a first power terminal that is accessed from the bottom surface of LED chip 14 and a second power terminal that is accessed from the top surface of LED chip 14. These power terminals are connected, respectively, to terminals 12 and 13. The first power terminal is connected via an electrically conducting adhesive layer 15 applied to the bottom surface of LED chip 14, and the second power terminal is connected via a lead wire 16.

A solid pellet 17 containing the phosphor particles is placed in an injection chamber 20 that is connected to a mold 21 that overlies the LED chip. The composition of pellet 17 will be discussed in more detail below. For the purposes of the present discussion it is sufficient to note that the pellet is constructed from a resin that will flow when heated and compressed. However, even during the flowing process, the viscosity of the material is sufficiently high to prevent the phosphor particles from settling.

The mold pellet in the injection chamber is heated and compressed so as to cause the pellet material to flow into mold 21 where it hardens into a phosphor layer 19 having the desired shape and which overlies LED chip 14 as shown in FIG. 3. It should be noted that if the phosphor particles in pellet 17 are uniformly distributed in the pellet material, the resultant phosphor cap 19 will also have a uniform distribution of phosphor particles. While the embodiment shown in FIG. 3 has a phosphor layer with a particular shape, embodiments in which the phosphor layer has different shapes can also be practiced.

A suitable phosphor molding compound composition for use in the present invention can be constructed from an optically clear epoxy resin. The epoxy resin accounts for more than 60% by weight of the final pellet. Suitable mold_compound can be purchased from Henkel-Loctite (MG18/Mg97), 211 Franklin Street, Olean, N.Y. 14760, USA.

The present invention can be used with a large variety of phosphors. For example, phosphors based on aluminum garnets such a Yttrium Aluminum Garnet (YAG:Ce); YAG:Ce,Pr; YAG:Ce,Th; Terbium Aluminum Garnet (TAG:Ce); Silicate phosphor (Ba,Ca,Sr)SiO4; the sulfides such as Strontium Sulfide (SrS) and thiogallates such as Strontium Thiogallate (SrGa₂S₄) may be utilized. Such phosphors are provided in the form of particles ranging from 1 μm to 30 μm and they have various shapes. Suitable phosphors are commercially available from Osram, Philips, or General Electric. As noted above, these phosphors typically have a high specific gravity and are prone to settling when mixed into a slurry form. It should also be noted that certain phosphors such as SrS or SrGa₂S₄ are moisture sensitive in that their wavelength conversion ability deteriorates upon prolonged exposure to moisture, and hence, must be protected from moisture. The phosphor component of the pellets is typically in the range of 0 to 35 percent by weight.

As noted above, the phosphor particles have a tendency to settle when suspended in the epoxy mixture prior to the curing of the epoxy. Accordingly, a thixotropic agent in an amount less than, or equal to, 8 percent by weight is added to prevent settling prior to the curing of the pellet material. Pyrogenic silicic acid may be used for the thixotropic agent.

The preferred pellet composition also includes a diffuser such as SiO₂ or TiO₂ in a concentration of less than, or equal to, 5 percent by weight. The diffusive agent aids in the suppression of color irregularities that can result from the larger luminescent material particles and increases the viscosity of the epoxy resin. The diffusive agent can also be incorporated with the luminescence material. Diffusing agents can be inorganic compounds such as Barium Titanate, titanium Oxide, aluminum oxide, silicone oxide, calcium carbonate etc. In addition, Organic diffusing agents such as melanin resin, CTU guanamine resin and benzoguanamine resin can also be used. The Diffusive agent preferably has a median particle size between 1 μm-5 μm. Because of the small size of the particles, the diffusive agent has a minimal effect on the light emitted from the diode, but can increase the viscosity of the epoxy resin itself with minimal alteration in the luminous intensity produced.

The preferred pellet composition also includes adhesion promoters in a concentration of less than or equal to 3 percent by weight to improve the adhesion between the phosphor cap and the underlying LED and surrounding surfaces. For example, adhesion promoters that include functional alkoxysiloxane improve the adhesion between the phosphor particles and the epoxy resin in the cured state of the molding composition.

If the phosphor composition is sensitive to moisture, the pellet composition also includes a hydrophobic agent to protect the phosphor particles from moisture. The hydrophobic agent is present in a concentration of less than 3 percent by weight. For example, liquid silicon wax can be used to modify the compatibility and wettability of inorganic material surfaces with the organic (epoxy) resin.

Finally, the pellet composition may also include a UV inhibitor at a concentration of less than, or equal to, 3 percent by weight to prevent the deterioration of the resin from UV exposure in applications in which the device will be exposed to an external UV source or in devices in which the LED generates UV. For example, resorcinol monobenzoate can be used as a UV inhibitor. This compound is available commercially from Eastman Chemical Products, US.

As noted above, the thixotropic agent is used to thicken the epoxy casting resin, so as to suspend the phosphor particles in the mold compound. This ensures that the phosphor is suspended homogeneously throughout the mold pellets. The molding compound is preferably a reaction product of a partially cured epoxy composition having the phosphor material substantially uniformly distributed therein. The molding compound is prepared by partially curing a homogeneous mixture of the epoxy composition and the phosphor material to increase the viscosity of the epoxy composition and suspend the phosphor material within the epoxy composition during mixing.

While the above-described embodiments of the present invention utilized specific phosphors and molding compound compositions, the present invention may be practiced with numerous other molding and phosphor compositions. In particular, any phosphor material that is capable of converting light emitted from an LED into visible light may be utilized. The phosphor material can be a phosphor which is capable of converting and emitting one color (broadband, narrow band or multi-line e.g. red, green, blue, yellow or white), or a mixture of phosphors which are capable of converting and emitting different colors to provide a desired output spectrum.

For example, the molding compound of the present invention can be used with an LED capable of generating UV and/or blue light to generate white-appearing light. In this case, the phosphor material converts such UV and/or blue light into visible white light. In particular, light having a wavelength in the range, between 400 to about 800 nm. The phosphor material is desirably provided in the form of particles, which can be intermixed within the epoxy composition.

Various modifications to the present invention will become apparent to those skilled in the art from the foregoing description and accompanying drawings. Accordingly, the present invention is to be limited solely by the scope of the following claims.

1. A composition comprising:
a suspension of phosphor particles that are uniformly distributed in a transparent medium comprising
an epoxy;
a thixotropic agent that thickens said epoxy;
a diffusive agent comprising diffusive particles of a transparent material, said diffusive agent having a concentration less than or equal to 5 percent by weight;
an adhesion promoter that improves the adhesion of said transparent medium to a semiconductor die, said adhesion promoter is present in a concentration less than or equal to 3 percent by weight; and
a UV inhibitor present in a concentration less than or equal to 3 percent by weight,
wherein said phosphor particles are coated with a hydrophobic agent that protects said phosphor particles from moisture, said hydrophobic agent is present in a concentration less than or equal to 3 percent by weight.

2. The composition of claim 1 wherein said diffusive particles have a median particle size between 1 μm-5 μm.

3. The composition of claim 1 wherein said diffusive agent comprises an inorganic compound.

4. The composition of claim 3 wherein said inorganic compound comprises Barium Titanate, titanium Oxide, aluminum oxide, silicone oxide, or calcium carbonate.

5. The composition of claim 1 wherein said diffusive agent comprises an organic compound.

6. The composition of claim 5 wherein said organic compound comprises melanin resin, CTU guanamine resin or benzoguanamine resin.

7. The composition of claim 1 wherein said adhesion promoter comprises a functional alkoxysiloxane.

8. The composition of claim 1 wherein said hydrophobic agent comprises a silicone wax.

9. The composition of claim 1 wherein said UV inhibitor comprises resorcinol monobenzoate.

10. The composition of claim 1 wherein said composition liquefies when placed under conditions of pressure and heat that are less than a pressure and a temperature that would damage a semiconductor die.

11. The composition of claim 1 wherein said composition is in the form of a pellet suitable for transfer molding.

12. A light emitting device comprising:
a semiconductor die having a light emitting device thereon that emits light at a first wavelength;
a suspension of phosphor particles that are uniformly distributed in a transparent medium comprising
an epoxy;
a thixotropic agent that thickens said epoxy;
a diffusive agent comprising diffusive particles of a transparent material, said diffusive agent having a concentration less than or equal to 5 percent by weight;
an adhesion promoter that improves the adhesion of said transparent medium to a semiconductor die, said adhesion promoter is present in a concentration less than or equal to 3 percent by weight; and
a UV inhibitor present in a concentration less than or equal to 3 percent by weight,
wherein said phosphor particles are coated with a hydrophobic agent that protects said phosphor particles from moisture, said hydrophobic agent is present in a concentration less than or equal to 3 percent by weight.

13. The light emitting device of claim 12 wherein said particles have a median particle size between 1 μm-5 μm.

14. The light emitting device of claim 12 wherein said diffusive agent comprises an inorganic compound.

15. The light emitting device of claim 14 wherein said inorganic compound comprises Barium Titanate, titanium Oxide, aluminum oxide, silicone oxide, or calcium carbonate.

16. The light emitting device of claim 12 wherein said diffusive agent comprises an organic compound.

17. The light emitting device of claim 16 wherein said organic compound comprises melanin resin, CTU guanamine resin or benzoguanamine resin.

18. The light emitting device of claim 12 further comprising an adhesion promoter that improves the adhesion of said transparent medium to a semiconductor die.

19. The light emitting device of claim 18 wherein said adhesion promoter is present in a concentration less than or equal to 3 percent by weight.

20. The light emitting device of claim 18 wherein said adhesion promoter comprises a functional alkoxysiloxane.

21. The light emitting device of claim 12 wherein said hydrophobic agent comprises a silicone wax.

22. The light emitting device of claim 12 wherein said UV inhibitor comprises resorcinol monobenzoate.

23. The light emitting device of claim 12 wherein said suspension liquefies when placed under conditions of pressure and heat that are less than a pressure and a temperature that would damage a semiconductor die.

24. The light emitting device of claim 12 wherein said suspension is in the form of a pellet suitable for transfer molding.
